(19) United States
(12) Patent Application Publication
(10) Pub. No.: US 2005/0082166 A1
(43) Pub. Date: Apr. 21, 2005

(54) Cathode structure for vacuum sputtering machine

(75) Inventor: Yuan-Jui Ho, Chu Pei City (TW)

Correspondence Address: TROXELL LAW OFFICE PLLC, SUITE 1404, 5205 LEESBURG PIKE, FALLS CHURCH, VA, 22041, US

(73) Assignee: Applied Vacuum Coating Technologies Co., Ltd.

(21) Appl. No.: 10/685,457

(22) Filed: Oct. 16, 2003

(51) Int. Cl. C23C 14/35

(52) U.S. Cl. 204/298.19; 204/298.17

(57) ABSTRACT

A cathode structure for vacuum sputtering machine is used for the sputtering process to be applied as a cathode structure for physical vapor deposition system. The cathode structure has the special function to modulate the assistant magnetic field to cause the consumption of target bar being very uniform. The cathode structure can fit the existing sputtering system to be provided in the application of deposition of electrical plasma material. The invention is usable in the field of electrical plasma deposition to substrate object (such as the application on the glass substrate or wafer). The life period of the target bar can be extended very long by using the invention from comparison with the conventional cathode structure. The cathode structure of the invention comprises a generator of assistant magnetic field, a target bar and a interference magnetic strip.

### FIELD OF THE INVENTION

The present invention relates to a cathode structure for vacuum sputtering machine used for the sputtering process to be applied as a cathode structure for physical vapor deposition system. The cathode structure has the special function to modulate the assistant magnetic field to cause the consumption of target bar being very uniform. The cathode structure can fit the existing sputtering system to be provided in the application of deposition of electrical plasma material. The invention is usable in the field of electrical plasma deposition to substrate object (such as the application on the glass substrate or wafer). The life period of the target bar can be extended very long by using the invention from comparison with the conventional cathode structure. Thus the present invention can be applied to cause the target bar in a proper application.

### BACKGROUND OF THE INVENTION

As acknowledged by the skilled person in the semiconductor industry, the vapor deposition equipment or plasma phase deposition equipment are the important objects for technical research and manufacturing project proceeding by the electrical equipment manufacturer. Specially the object of the physical vapor deposition system being able to execute its function, the relative technical area includes sputtering structure area, the special assistant device for each equipment, and control software coordination system, being constructed by the combination of many technical areas. Wherein the special assistant device is a rather important factor to the entire machine system that the construction technique is relative to many professional industrial techniques for a skilled person to implement the application by acknowledgement of every relative professional technique area. Such as the technique of a wide range of average consumption mode of the target bar of vacuum sputtering machine is desired. If the said technique of target bar improvement is applied, the life of the target bar can be extended to cause the cost down effect of the deposition thin film. In addition, the improvement of the existing vacuum sputtering machine is also very important and the low cost consideration in the improvement design is not avoidable. Thus the multiple considerations are the basic requirement for the improvement of the vacuum sputtering machine. The suitable design for improvement is the major object for every manufacturer to research.

The kinds of the vapor deposition should be simply described herein. Firstly the vapor deposition of thin film can be sorted to two categories by the deposition process containing chemical reaction or not. The two kinds of the process are Chemical Vapor Deposition (CVD) and Physical Vapor Deposition (PVD). The deposited thin film can be single crystal, poly-crystal or amorphous.

In the conventional sputtering system for thin film deposition on wafer, it exists an old type cathode structure shown in FIG. 1 and FIG. 2 as reference. Wherein the target bar 1 receives the electrical particles bombardment at the outer side surface 15 to generate the electrical plasma for vapor deposition. The target bar 1 is fixed at the inner side surface 17 by Indium connection structure 11 to fix on the connection carrier plate 13 or the assistant magnetic field generating device 2(includes the cathode electrical field). Wherein the the assistant magnetic field generating device 2 is arranged at the position above the support frame 22(includes the anode electrical field). Wherein the assistant magnetic field generating device 2 has the magnetic pole 21 inside being able to generate the assistant magnetic field to assist the sputtering process proceeding. But the conventional cathode structure (in FIG. 1 and FIG. 2) can only provide the fundamental sputtering function. It cause the target bar 1 consumed to establish V shape corrosion section 53 shown in the FIG. 7. If we hope to enhance the usage of target bar 1, depending on current technique it is necessary to add a movable module (not shown in the figures) on the assistant magnetic field generating device 2 to generate the U shape corrosion section 51 of target bar 1 shown in the FIG. 8. But the movable module will occupy a large space and can not be applied on all the sputtering machine that will not be suitable on practical application. So the important researching object has been generated for the improvement of vacuum sputtering machine by the specific manufacturer.

The basic principle and structure of the sputtering system should be described in the following for sufficient support to the specification. The electrical plasma is partially ionized gas. By the electrical voltage applied on the two relative metal electrodes and the gas concentration within certain range, the surface of the electrode will generate secondary electrons by ion bombardment to be energized by the electrical field generated by the electrodes to cause the gas molecules between the electrodes to create the reaction of dissociation, ionization, and excitation. The said reaction will generate the ion particles, atomic particles, atomic group particles, and more electrons to cause a concentration balance within electrical plasma particles. After the ion particles generate the bombardment on the cathode, from obeying the momentum transfer principle, the ion bombardment will generate secondary electrons in accordance with striking the atoms inside the surface out of the cathode, the special effect being named as “Sputtering”. The atoms stroked from the cathode will enter the electrical plasma. Therefore the plasma particles will be transferred by their kinetic energy and the diffusion effect to the surface of the coating object to establish deposition. This kind of specific PVD process to generate deposition film from gas phase and ion bombardment is so-called “sputtering deposition”. From the above described model, the structure of sputtering deposition is mainly divided into several steps: (1) part of the ion particles move from the electrical plasma area to the cathode, (2) the speeded ion particles bombard on the surface of cathode plate to generate the secondary electrons and to strike the atomic particles out of the cathode plate, (3) the stroke atomic particles enter the electrical plasma and finally transfer to a surface of the coating object (such as wafer, glass) placed on an electrode plate. (4) the thin film deposition is proceeded on the coating object by the said atomic particles with adsorbing process.

From the above mentioned conventional vacuum sputtering machine and the conventional movable module causing the low cost electrical plasma, we can find that we should research to develop a new cathode structure being suitable applied in wide range. Thus the low cost electrical plasma to generate thin film deposition can be established. Thus the inventor use the interference magnetic strip introduced into the assistant magnetic field as the major consideration to establish the structure of the present invention.

### SUMMARY OF THE INVENTION

It is the object of the present invention to provide a cathode structure to meet the requirement of the vacuum sputtering machine and to fit the variety kinds of vacuum sputtering machines that can be applied in the photoelectric and semiconductor areas to provide low cost electrical plasma by simple structure to establish a very valuable invention.

In order to reach the above purpose, the inventor improves the cathode structure of the conventional vacuum sputtering machine by adding the interference magnetic strip into the existing assistant magnetic field. Thus the present invention of cathode structure of vacuum sputtering machine is developed for the electrical plasma material deposition.

The present invention comprise: an assistant magnetic field generating device being connected to the mechanical structure of the vacuum sputtering machine, and having the ability to generate the assistant magnetic field; a target bar being connected to the cathode of a electrical field, the target bar having a inner side surface, a outer side surface, the inner side surface facing the assistant magnetic field generating device, and the outer side surface facing the bombardment electrical particles of the vacuum sputtering machine; and an interference magnetic strip being made of magnetic material and placed at the position between the target bar and the assistant magnetic field generating device; whereby the effect of the interference magnetic strip can interfere the assistant magnetic field, the bombardment electrical particles can bombard the target bar more uniform.

The various objects and advantages of the present invention will be more readily understood from the following detailed description when read in conjunction with the appended drawing, in which:

### BRIEF DESCRIPTION OF THE DRAWING

FIG. 1 shows a schematic view of a cathode structure of the conventional vacuum sputtering machine;

FIG. 2 shows a schematic view of another embodiment of a cathode structure of the conventional vacuum sputtering machine;

FIG. 3 shows a schematic view of the present invention of the cathode structure of the vacuum sputtering machine;

FIG. 4 shows a schematic view of another embodiment of the present invention of the cathode structure of the vacuum sputtering machine;

FIG. 5A shows a characteristic data table of the magnetic field of the present invention in measurement of practical application;

FIG. 5B shows a planning area of the present invention in measurement of practical application;

FIG. 5C shows a whole curve formed by characteristic data of the magnetic field of the present invention in measurement of practical application;

FIG. 6A shows a characteristic data table of the magnetic field of the target bar of the present invention in measurement of practical application;

FIG. 6B shows a planning area of the target bar of the present invention in measurement of practical application;

FIG. 6C shows a whole curve formed by characteristic data of the magnetic field of the target bar of the present invention in measurement of practical application;

FIG. 7 shows a consumption condition of target bar of the conventional technique;

FIG. 8 shows a consumption condition of target bar of the present invention or improved cathode structure

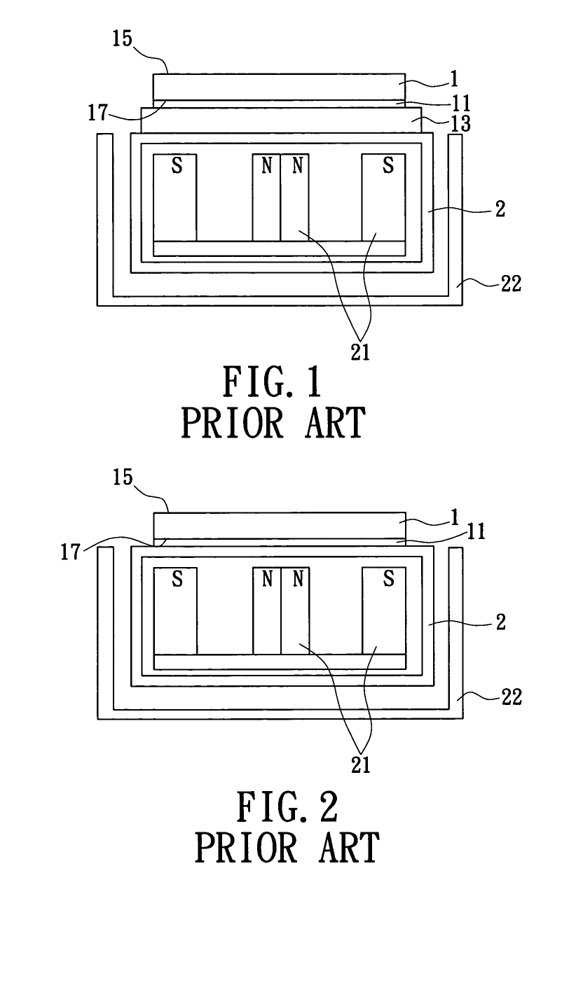

### DETAILED DESCRIPTION OF THE INVENTION

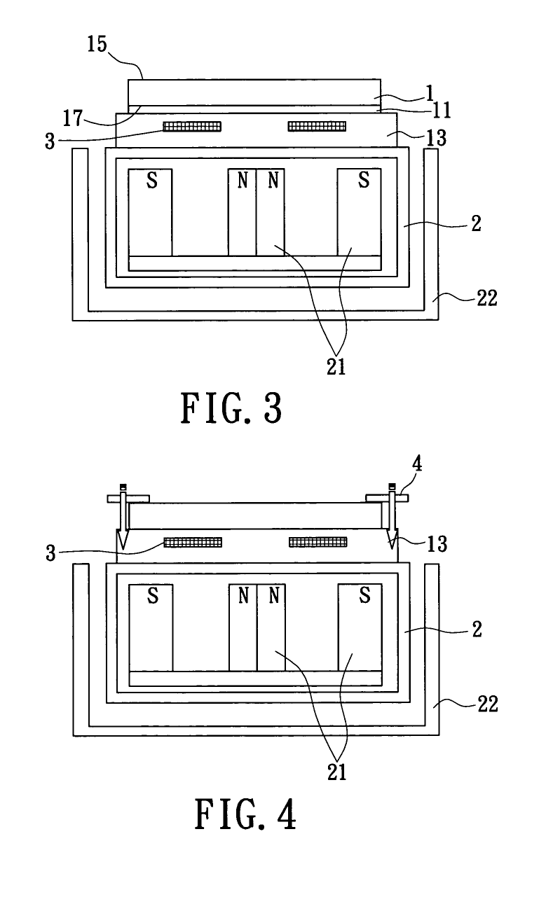

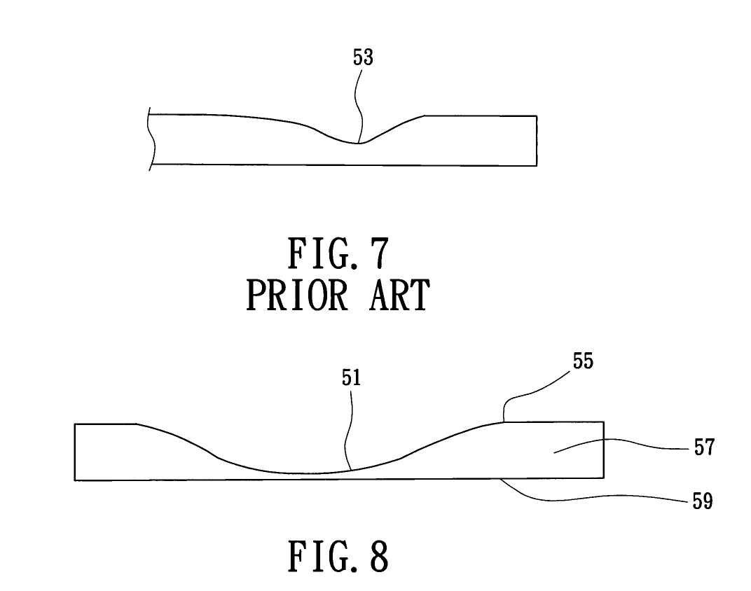

As shown in FIG. 3 and FIG. 4, the present invention of the cathode structure of the vacuum sputtering machine is shown in them. These two figures show each of the important features by partial cross section and the major devices to illustrate the present invention. The global structure is similar to the conventional structure except for adding a interference magnetic strip 3. Firstly the detail description should be here added to explain the structure of the present invention. It is well known for the all the skilled person that the assistant magnetic field has the function to assist the vacuum sputtering system to generate the electrical plasma from a cathode therein. This is from the reason of guiding the electrical particles to bombard the target bar 1. But the normal assistant magnetic field can only concentrate the electrical particles in a very narrow range to bombard the target bar 1. The action will cause the consumption of the target bar 1 being concentrated in a very small area to make the new replacement of target bar 1 at the low consumption stage. It is not economic for cost structure. Under adding the interference magnetic strip 3, the shape of the assistant magnetic field has been changed to allow the electrical particles acting in a larger bombardment area. Thus the consumption condition of target bar 1 will be changed from the V shape corrosion section 53 shown in the FIG. 7 to U shape corrosion section 51 shown in the FIG. 8. The reason of this improvement is the interference magnetic strip is made of magnetic material that can be permanent magnet or temporary magnetism material to improve the assistant magnetic field changed from the magnetic density shape being concentrating in small area to the magnetic density shape of uniform distributed in wider area. Thus the improved effect can guide the bombarding electrical particles to bombard the target bar 1 in a wider area to enhance the application life period of the target bar1.

The technical description of magnetic material should be disclosed here. The magnetic material is a kind of “the material having the ability to induct the magnetism or to generate the magnetism”. Most of the magnetic materials mainly comprise or transferred from the elements of Fe, Co, Ni. The sorting method of magnetic material can be divided into three kinds such as permanent magnet, temporary magnetism material and semi-permanent magnetism material( the specific material used to be applied on the area to record the voice and image, being in need of semi-permanent magnetism property). Another sorting method for magnetic material is divided into high inductivity magnetic material, magnet, and the record media. The temporary magnetism material is also called the ferro-oxide magnetic core and is a kind of magnetic material without natural magnetism. But such kind of temporary magnetism material is very easy to be inducted with magnetism and to be removed the magnetism, being with the high inducting magnetism ability and high electrical resistance. This kind of temporary magnetism material mainly comprises the powder of ferro-oxide and other metal material such as Mn, Zn, and Ni. In addition, the high electrical resistance can reduce the inductive current and is suitable be applied on the high frequency, being widely applied on the high frequency transformer and varieties of the inductor core. Many kinds of products such as computer, telephone, TV recording device, and image/voice device are necessary to use the temporary magnetism material. The present invention is preferred to use the temporary magnetism material but it is also allowable to use the permanent magnet.

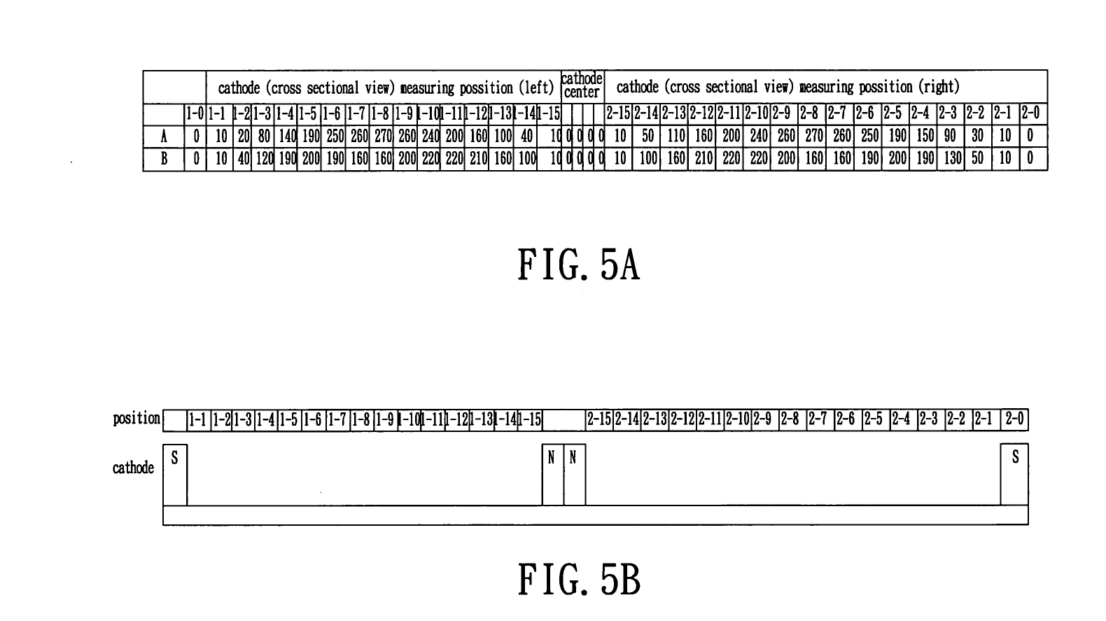

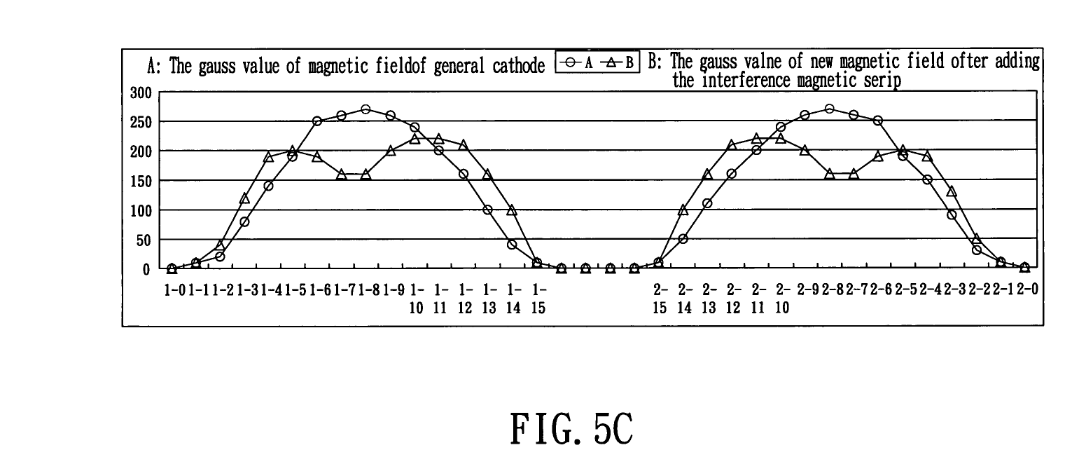

Please refer to the FIG. 5A, FIG. 5B, and FIG. 5C, these are the strength of the magnetic field comparison in Gauss value between the cathode structure of present invention and the conventional cathode structure. The FIG. 5A describes the locations and the values. The FIG. 5B shows the arrangement of target bar 1 and the assistant magnetic field. The FIG. 5C directly shows the effect of the present invention by the curve sketching from reference data values. Wherein the FIG. 5C apparently shows that the conventional assistant magnetic field is single peak shape. Thus the magnetic field in single peak shape causes the V shape corrosion section 53 in FIG. 7 and this effect is not hard to be understood. In the comparison to the conventional method, the present invention has excellent strength distribution of magnetic field in the Gauss value curve shape of twin peaks. It is apparently to recognize the special functional effect generated from the interference magnetic strip 3 shown in the FIG. 3 and FIG. 4. Thus the such interference effect causes the consumption type of the target bar 1 to a better condition of U shape corrosion section 51. From the above description and figures, the present invention having the practical property and basic principle are clearly disclosed. The reference data in the figures are base on the simple shape of target bar 1 in rectangular body to measure in the practical application.

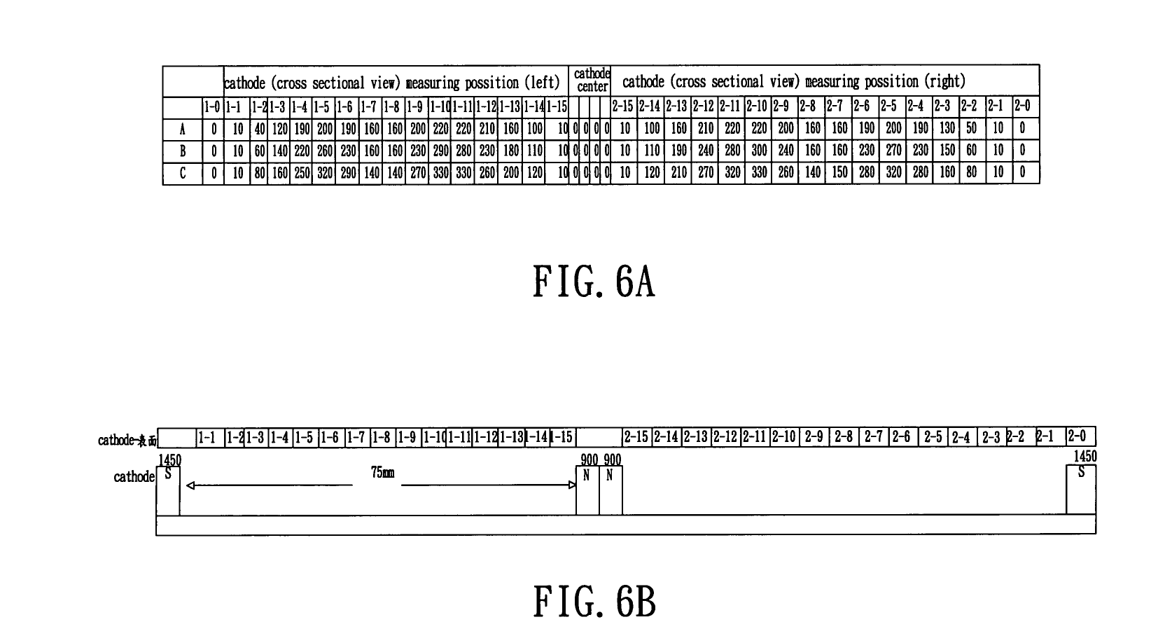

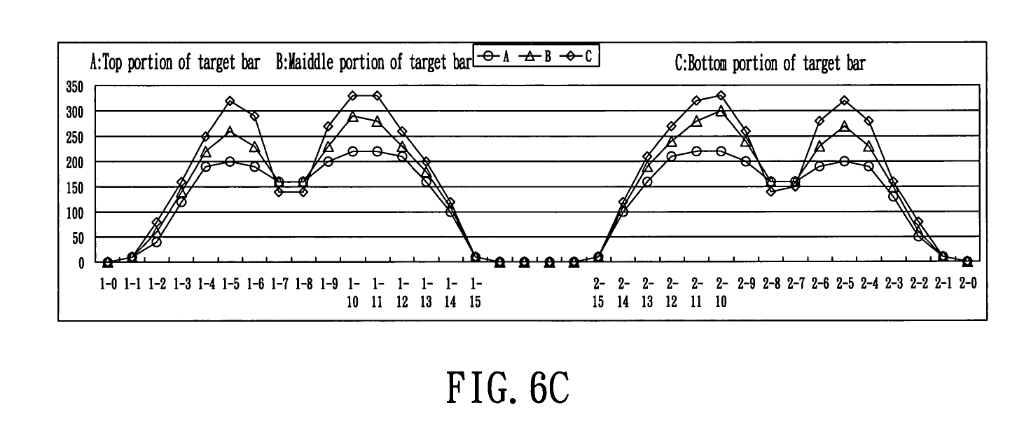

Please also refer to the FIG. 6A, FIG. 6B, FIG. 6C, and FIG. 8 for the strength distribution of the magnetic field within the every part of the target bar 1 that these figures record the relative data of the target bar 1. Wherein the top portion of target bar 55, middle portion of target bar 57, and bottom portion of target bar 59 having different magnetic strength distribution showing in the FIG. 6C during the application period of the present invention. Wherein the FIG. 6A shows the location period and the Gauss value. The FIG. 6B shows the arrangement of target bar 1 and the assistant magnetic field. The FIG. 6C shows the effect of present invention at every part the target bar 1. From observing the FIG. 6C, the target bar 1 in the present invention has the magnetic field distribution trend from violent variation toward smooth slope being measured from the bottom side to the top side of the target bar 1. The trend shows that the present invention has better characteristic at the main application area( top side of the target bar 1).

The life extended value of various kinds of the target bars 1 (caused by the present invention) is further disclosed here. Under the same operation parameters of working machine, vacuum degree, and power to proceed the present invention, metal target bar 1( Ti, Nb, Cr, 8 mmt) can extend the working life in 50 percent, nonmetal target bar 1(Si, 6mmt) extending the working life in 57 percent, metal oxide target bar 1(ITO, TiO, ZnO, 6 mmt) extending the life in 200 percent.

Further detail description for the structure of the present invention should be present in the below, the present invention comprises: an assistant magnetic field generating device 2 being connected to the mechanical structure of the vacuum sputtering machine, and having the ability to generate the assistant magnetic field; a target bar 1 being connected to the cathode of a electrical field, the target bar having a inner side surface 17, a outer side surface 15, the inner side surface 17 facing the assistant magnetic field generating device, and the outer side surface 15 facing the bombardment electrical particles of the vacuum sputtering machine; and an interference magnetic strip 3 being made of magnetic material and placed at the position between the target bar 1 and the assistant magnetic field generating device 2; whereby the effect of the interference magnetic strip 3 can interfere the assistant magnetic field, the bombardment electrical particles can bombard the target bar 1 more uniform.

It is necessary to further describe the other various kinds of embodiment of the present invention. The present can further comprise a connection carrier plate 13 (preferring made by metal) being positioned between the target bar 1 and the assistant magnetic field generating device 2, and the interference magnetic strip 3 being installed in the connection carrier plate 13. In addition, the present invention can further comprises an Indium connection structure 11 placed between the target bar 1 and the connection carrier plate 13. The present invention can further comprise an elastic fastening mechanism 4 to fasten the target bar 1 on the connection carrier plate 13. Wherein the interference magnetic strip 3 can be made by the permanent magnet or the interference magnetic strip 3 can be made by the temporary magnetism material.

The major inventive portion of the present invention is to use the interference magnetic strip 3 to insert into the conventional assistant magnetic field, it being different from the simple conventional assistant magnetic field established by the magnets for the sputtering system. The difference of the assistant magnetic field can be clearly identified by their Gauss value.

The basic principle of the present invention is only considering to modify the shape, thickness, and the distance to the magnet in the assistant magnetic field to get every kinds of preferred assistant magnetic field for sputtering. It is due to the generation of the wider sputtering magnetic field can be achieved and the strength of the magnetic field can be varying in the perpendicular direction relative to the surface of the target bar 1.

The advantage of the present invention is to generate more wider and deeper magnetic field for sputtering system at the same dimension of the cathode structure. Thus the conventional V shape corrosion section 53 can be changed to U shape corrosion section 51. In addition, the more sputtering particles can be generated at the same operation condition. Because of the wider sputtering area being generated, the bombardment effect can be improved to let the sputtering particles more active to add into the reaction gas to reach the coating work piece. Thus we can use lower power to finish the same thickness of coating film. Further the sputtering magnetic field is affected by the interference magnetic strip 3 to form a uniform consumption shape on the target bar 1, being established a low cost structure of wide assistant magnetic field. The modulation of the cathode structure by the present invention can adapted to the various kinds of the target bar 1 to generate the sputtering particles. The above feature can generate the below benefits: 1. the life of the target bar can extend 50-200 percents at the same sputtering condition. It is very helpful to reduce the manufacturing cost. 2. Not only the life of the target bar 1, but also the steady state of the consumption rate of the target bar 1 can improve the quality of the work piece. Thus the productivity can add more 15 percents.

Summarily, the present invention is a scarce new article and full of industrial application ability, novelty and inventive step. It is fully conformed to the patent ability. Now refer to the corresponding rules to propose the patent application, and please give detail examination and kindly grant the patent allowance to protect the right of the inventor.

Although the present invention has been described with reference to the preferred embodiment thereof, it will be understood that the invention is not limited to the details thereof. Various substitutions and modifications have suggested in the foregoing description, and other will occur to those of ordinary skill in the art. Therefore, all such substitutions and modifications are intended to be embraced within the scope of the invention as defined in the appended claims.

1. A cathode structure for a vacuum sputtering machine, which comprise:
an assistant magnetic field generating device being connected to the mechanical structure of the vacuum sputtering machine, and having the ability to generate the assistant magnetic field;
a target bar being connected to the cathode of a electrical field, the target bar having a inner side surface, a outer side surface, the inner side surface facing the assistant magnetic field generating device, and the outer side surface facing the bombardment electrical particles of the vacuum sputtering machine; and
an interference magnetic strip being made of magnetic material and placed at the position between the target bar and the assistant magnetic field generating device;
whereby the effect of the interference magnetic strip can interfere the assistant magnetic field, the bombardment electrical particles can bombard the target bar more uniform.

2. The cathode structure for a vacuum sputtering machine as claimed in claim 1, further comprises a connection carrier plate being positioned between the target bar and the assistant magnetic field generating device, and the interference magnetic strip being installed in the connection carrier plate

3. The cathode structure for a vacuum sputtering machine as claimed in claim 2, further comprises an Indium connection structure placed between the target bar and the connection carrier plate.

4. The cathode structure for a vacuum sputtering machine as claimed in claim 2, further comprises an elastic fastening mechanism to fasten the target bar on the connection carrier plate.

5. The cathode structure for a vacuum sputtering machine as claimed in claim 1, wherein the interference magnetic strip is made by the permanent magnet

6. The cathode structure for a vacuum sputtering machine as claimed in claim 1, wherein the interference magnetic strip is made by the temporary magnetism material
